(19) United States
(12) Patent Application Publication
(10) Pub. No.: US 2025/0071950 A1
(43) Pub. Date: Feb. 27, 2025

(54) LIQUID COOLING HEAT EXCHANGE DEVICE FOR DATA ROOM

(71) Applicant: Hebei Qinhuai Data Co., Limited., Zhangjiakou City (CN)

(72) Inventor: Binghua ZHANG, Zhangjiakou City (CN)

(21) Appl. No.: 18/810,233

(22) Filed: Aug. 20, 2024

(30) Foreign Application Priority Data
Aug. 23, 2023 (CN) 202311068268.4

(51) Int. Cl. H05K 7/20

(52) U.S. Cl. CPC H05K 7/2079; H05K 7/20263; H05K 7/20272; H05K 7/20836

(57) ABSTRACT

The present disclosure discloses a liquid cooling heat exchange device for a data room, which can accurately regulate temperature of a coolant in a liquid-cooled server container, cool and filter the coolant in the liquid-cooled server container, meet requirements for heat dissipation of a liquid-cooled server, and ensure that the server can run normally for a long time. Through reasonable structural design, the liquid cooling heat exchange device can complete daily maintenance better and faster than similar devices.

### CROSS REFERENCE TO RELATED APPLICATION

This application claims priority to Chinese Patent Application No. 202311068268.4, titled “LIQUID COOLING HEAT EXCHANGE DEVICE FOR DATA ROOM” and filed to the China National Intellectual Property Administration on Aug. 23, 2023, the entire contents of which are incorporated herein by reference.

### TECHNICAL FIELD

The present disclosure relates to the field of liquid cooling technology for a data center, and more particularly, to a liquid cooling heat exchange device for a data room.

### BACKGROUND

According to survey and research made by many enterprises and scholars, energy consumption of refrigeration systems ranks second in total energy consumption of data centers, accounting for about 35%. Therefore, reducing refrigeration energy consumption is a direct and efficient way to improve efficiency of energy utilization for the data centers. At present, main refrigeration methods for the data centers are divided into two categories: air cooling and liquid cooling. As requirements for energy consumption increase, the traditional air cooling method is difficult to meet increasing requirements for computing power, and the data center refrigeration industry will usher in a reshuffle, and the liquid cooling gradually is used more widely. At present, servers of many data centers use air cooling technologies for heat dissipation. That is, air is used to cool. However, the air is not a good refrigerant. If the liquid cooling is used, its cooling effect is 1000 to 3000 times higher than the air. Problems of higher energy consumption and lower performance that cannot be solved by the air cooling can be significantly improved by the liquid cooling technologies. The servers thus achieve higher density, lower noise, lower heat transfer temperature difference, and natural cooling effects throughout a year.

However, although the liquid cooling technologies have advantages over the air cooling technologies in some aspects, there are also some problems and challenges. For example, lower utilization of natural cold sources is unable to regulate and control temperature of the servers in the data rooms. Furthermore, the traditional air cooling technologies have higher energy consumption and water resource consumption. Moreover, existing liquid cooling heat exchange devices are larger in size and poorer in temperature regulation ability, and are not convenient in subsequent maintenance. Therefore, it is required to develop new liquid cooling heat exchange devices to solve the above problems.

### SUMMARY

To solve problems of the prior art, embodiments of the present disclosure provide a liquid cooling heat exchange device for a data room. The technical solutions are described as follows.

In one aspect, there is provided a liquid cooling heat exchange device for a data room, including a server container, an external circulation system, a pipeline system, a sensor, a control system, and a structural member.

The server container includes a server container liquid-outlet port and a server container liquid-inlet port, where the server container liquid-outlet port is connected to a coolant outlet inside the server container, and the server container liquid-inlet port is connected to a coolant inlet inside the server container.

The external circulation system includes an external circulation coolant and a heat dissipation system, where the external circulation coolant enters a plate heat exchanger to participate in heat exchange after the coolant is subjected to outdoor heat dissipation by means of the heat dissipation system, and the external circulation system is configured to cool the coolant in the server container by means of the plate heat exchanger.

The pipeline system adopts a stainless steel pipeline, and the pipeline system is configured to guide the coolant in the server container into the plate heat exchanger, and guide the coolant cooled by the plate heat exchanger back to the server container.

The sensor is mounted in a key pipeline to monitor a parameter of a liquid inside the pipeline in real time.

The control system is connected to the sensor and an actuator, and is configured to control the actuator by calculating a control instruction according to data collected by the sensor, to regulate a flow rate and a temperature of the coolant in the server container, thereby accurately controlling the temperature of a server.

Further, the pipeline system also includes a right-angle filter, which is arranged on a pipeline of the server container liquid-inlet port.

Further, the sensor includes a flowmeter, a temperature sensor, and a pressure sensor. The flowmeter is arranged on a pipeline of the server container liquid-outlet port, the temperature sensor is arranged on a pipeline of the server container liquid-inlet port or server container liquid-outlet port, and the pressure sensor is arranged on a pipeline of the external circulation system.

Further, the control system is a PLC control system or a DCS control system.

Further, the actuator includes a pump and an electric regulating valve, where the pump is arranged on the pipeline of the server container liquid-outlet port, and the electric regulating valve is arranged on the pipeline of the external circulation system.

Further, the pipeline system is also provided with a manual valve, which includes one or more of a ball valve, a butterfly valve, and a stop valve.

Further, the pipeline system is also provided with a liquid filling/discharging port, which is arranged on a pipeline of the pump.

Further, the pipeline system is also provided with a flexible pipe section, which is arranged on a pipeline of the pump.

Further, the structural member is made of stainless steel, and the structural member is configured to fix apparatuses such as the server container port, the plate heat exchanger, the pipeline system, the sensor, and the actuator together.

Further, the plate heat exchanger is configured to cool the coolant in the server container by means of the external circulation coolant, and precisely regulate a parameter of the coolant by means of the sensor and the control system, to accurately control the temperature of the server.

The technical solutions provided by the embodiments of the present disclosure achieve the following beneficial effects.

The present disclosure provides a liquid cooling heat exchange device for a data room, which can accurately regulate temperature of a coolant in a liquid-cooled server container, cool and filter the coolant in the liquid-cooled server container, meet requirements for heat dissipation of a liquid-cooled server, and ensure that the server can run normally for a long time. Through reasonable structural design, the liquid cooling heat exchange device can complete daily maintenance better and faster than similar devices. The present disclosure can solve problems of inconvenient maintenance and high costs caused by failure of proper functioning of servers encountering local hot spots due to lower utilization rate of natural cold source for air conditioning in a data center and uneven air supply temperature.

### BRIEF DESCRIPTION OF THE DRAWINGS

To describe the technical solutions in the embodiments of the present disclosure more clearly, the following will briefly introduce the accompanying drawings required for describing the embodiments. Apparently, the accompanying drawings in the following description show merely some embodiments of the present disclosure, and a person of ordinary skill in the art may still derive other drawings from these accompanying drawings without creative efforts.

FIG. 1 is a front view of a liquid cooling heat exchange device for a data room according to an embodiment of the present disclosure;

FIG. 2 is a left view of a liquid cooling heat exchange device for a data room according to an embodiment of the present disclosure;

FIG. 3 is a right view of a liquid cooling heat exchange device for a data room according to an embodiment of the present disclosure;

FIG. 4 is a top view of a liquid cooling heat exchange device for a data room according to an embodiment of the present disclosure; and

FIG. 5 is an upward view of a liquid cooling heat exchange device for a data room according to an embodiment of the present disclosure.

### DETAILED DESCRIPTION

To make the objectives, technical solutions and advantages of the present disclosure clearer, the embodiments of the present disclosure will be further described as below in details with reference to the accompanying drawings.

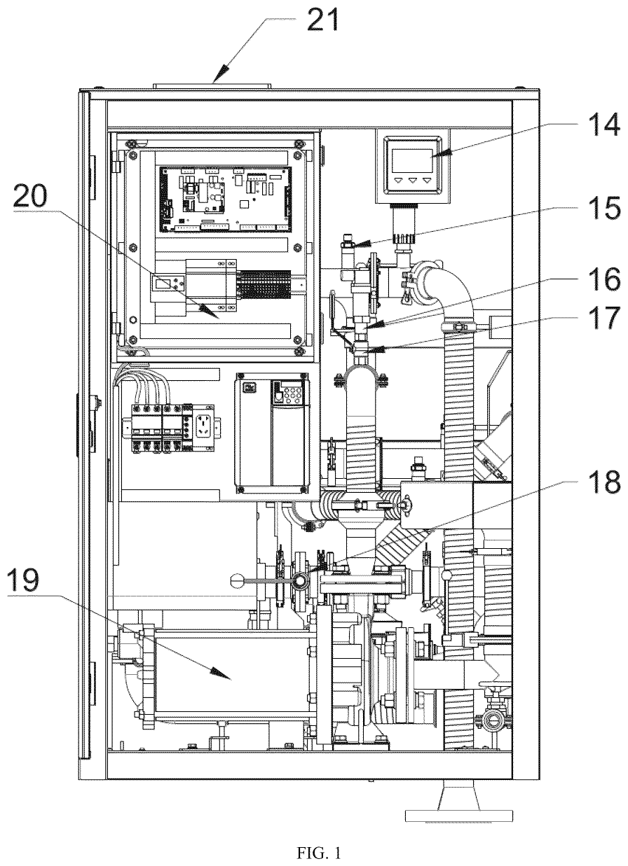

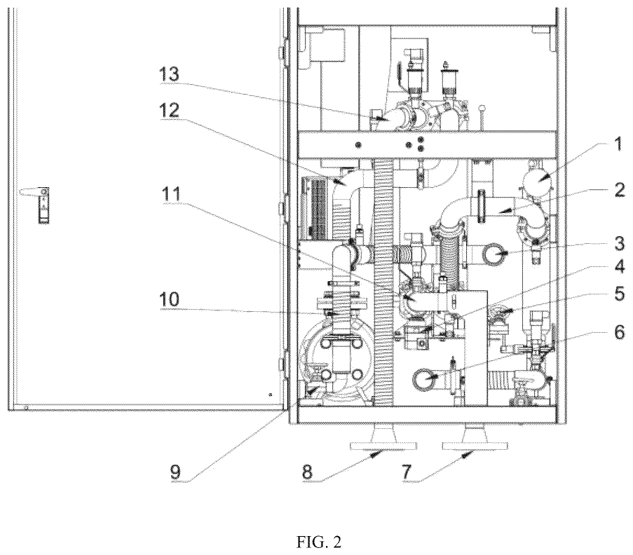

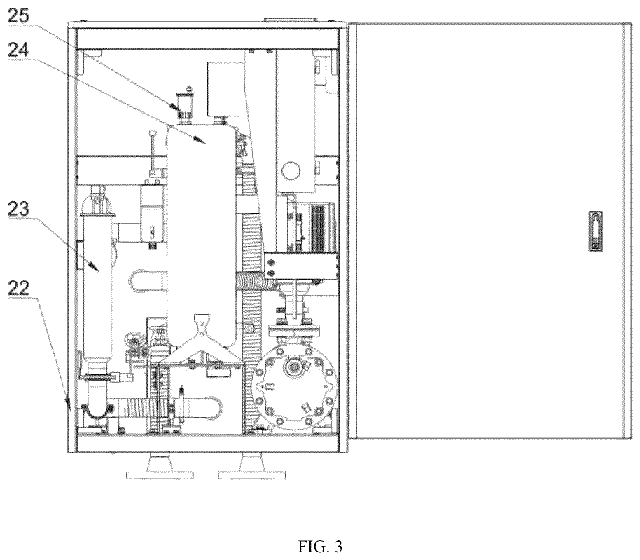

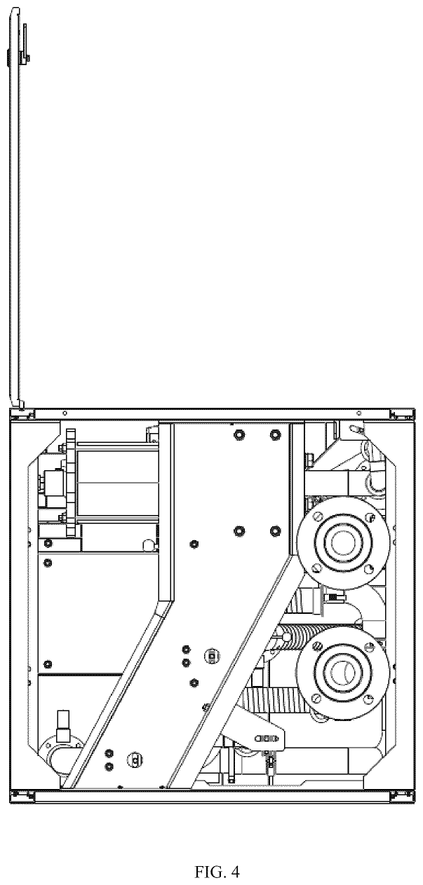

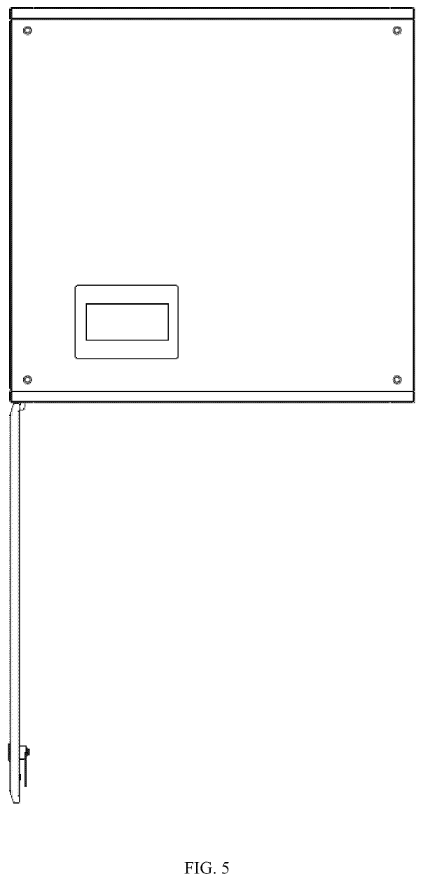

The present disclosure provides a liquid cooling heat exchange device for a data room. As shown in FIGS. 1 to 5, the liquid cooling heat exchange device for the data room includes: a flowmeter 1, a welded pipeline 2 before a right-angle filter, a server container liquid-outlet port 3, and an electric regulating valve 4; an external circulation liquid inlet pipe discharging stop valve 5; a server container liquid-inlet port 6, a liquid inlet flange 7 for an external circulation system, a liquid return flange 8 for the external circulation system, a pump inlet liquid filling/discharging port 9, a pump inlet welded pipe 10; a liquid inlet pipe welded pipe 11 for the external circulation system, a pump outlet welded pipe 12, a liquid return pipe welded pipe 13 for the external circulation system, a conductivity meter and controller 14, a temperature sensor 15, a pressure sensor 16, a ball valve 17, a cassette butterfly valve 18, a pump 19, an electrical and control system 20, a touch screen 21, a structural member 22, a right-angle filter and welded pipeline 23, a plate heat exchanger 24, and an automatic exhaust valve 25.

The device is connected to a liquid-cooled server container and an external heat dissipation system through stainless steel pipes to achieve temperature regulation and filtration of a coolant inside the server container. Operating principles of the device are as below. When temperature of the coolant inside the server container rises, the coolant enters a pipeline system of the device through the server container liquid-outlet port 3, and then enters the pump 19 after the flowmeter 1 measures a flow rate. The pump 19 provides circulating power to the coolant and pushes it to the plate heat exchanger 24. As an efficient heat exchange device, the plate heat exchanger 24 is comprised of a plurality of thin metal plates, where a channel is formed between every two of the plurality of thin metal plates. Two sides of the plate heat exchanger 24 are connected to the coolant inside the server container and the coolant inside the external heat dissipation system. When the two coolants flow in the plate heat exchanger 24, they exchange heat between adjacent channels. The metal plates of the plate heat exchanger 24 have higher thermal conductivity properties and larger heat transfer areas, thus efficient heat exchange can be achieved. By means of the plate heat exchangers 24, the coolant inside the server container transfers its excess heat to the coolant of the external heat dissipation system, thereby reducing its own temperature. After passing through the plate heat exchanger 24, the coolant inside the server container is filtered by means of the right-angle filter 23 to remove impurities and particles to protect safety of the server. Next, the coolant inside the server container flows back into the server container through the server container liquid-inlet port 6 to continue cooling the server.

As a system that uses natural energy to dissipate heat, the external heat dissipation system includes an external circulation coolant and a heat dissipation system. The external circulation coolant may be water or other low-temperature and low-pressure fluid. The heat dissipation system may be an air cooling tower, a water cooling tower, a buried pipe, or any other apparatus that can dissipate heat using natural environment. The external heat dissipation system is connected to the device through stainless steel pipes and forms a closed cycle with the plate heat exchanger 24. When temperature of the coolant inside the external heat dissipation system is lower than that of the coolant inside the server container, the coolant inside the external heat dissipation system enters the pipeline system of the device through the liquid inlet flange 7 for the external circulation system, and enters the plate heat exchanger 24 after its flow rate and pressure are regulated by means of the electric regulating valve 4. In the plate heat exchanger 24, the coolant inside the external heat dissipation system exchanges heat with the coolant inside the server container, thereby absorbing heat of the coolant inside the server container to increase its own temperature. After passing through the plate heat exchanger 24, the coolant inside the external heat dissipation system flows back to the external heat dissipation system through the liquid return flange 8 for the external circulation system, and excess heat is distributed to the natural environment by means of the heat dissipation system, such that the temperature of the coolant is reduced. Next, the coolant enters the device again for circulation.

The device is also equipped with a sensor and a control system, where the control system is connected to the sensor and an actuator to achieve precise control of the temperature of the coolant inside the server container. The sensor of the device includes the flowmeter 1, the temperature sensor 15, the pressure sensor 16, the conductivity meter 14, and so on. The flowmeter 1 is configured to monitor the flow rate of the coolant inside the server container and transmit flow rate data to the control system. The temperature sensor 15 is configured to detect inlet and outlet temperature of the coolant inside the server container and the inlet temperature of the external heat dissipation system, and transmit temperature data to the control system. The pressure sensor 16 is configured to detect pressure of the coolant inside the server container and pressure of the coolant inside the external heat dissipation system, and transmit pressure data to the control system. The conductivity meter 14 is configured to detect conductivity of the coolant inside the server container, determine quality and contamination degree of the coolant, and transmit conductivity data to the control system. The control system may be a PLC control system or DCS control system, and includes a touch screen 21, and an electrical and control system 20, etc. The touch screen 21 is configured to display an operating status of the device and set relevant operating parameters of the touch screen. The electrical and control system 20 is configured to receive the data collected by the sensor, calculate appropriate control instructions according to the preset parameters and algorithms, and output the control instructions to the actuator to regulate the flow rate and the temperature of the coolant inside the server container.

The actuator of the device includes a pump 19, an electric regulating valve 4 and so on. The pump 19 is configured to provide circulating power to the coolant inside the server container and to regulate rotational speed and power according to the control instructions. The electric regulating valve 4 is configured to regulate flow rate and pressure of the coolant inside the external heat dissipation system and to regulate switching amplitude according to the control instructions.

The device is also equipped with some manual valves and a liquid filling/discharging port to facilitate maintenance and repair of the device. The manual valves of the device include one or more of a ball valve 17, a butterfly valve 18, and a stop valve. The ball valve 17 is configured to install the pressure sensor and can be closed when the pressure sensor needs maintenance. The butterfly valve 18 is configured to connect the electric regulating valve 4 to the plate heat exchanger 24 and can be closed when other components such as the electric regulating valve 4 or the plate heat exchanger 24 require maintenance. The stop valve is configured to connect the server container liquid-outlet port 3 to the server container liquid-inlet port 6 and may be closed when the server container needs maintenance. The liquid filling/discharging port 9 of the device is arranged on a pipeline of the pump 19, such that the coolant is filled or discharged during maintenance or repair of the device.

Specifically, the external circulation liquid inlet pipe discharging stop valve 5 is mainly used for discharging the liquid in the pipeline when the device needs maintenance.

The device is also provided with some flexible pipe sections to compensate for size and assembly errors, and to reduce impact of vibration caused by operation of the pump 19 on other components. The flexible pipe sections of the device are arranged on the pipeline of the pump (19) and are made of corrugated stainless steel hoses.

The structural member 22 of the device is made of stainless steel, which has good corrosion resistance and mechanical strength. The structural member 22 of the device fixes the server container port, the plate heat exchanger 24, the pipeline system, the sensor, and the actuator together to ensure stability and integrity of the device.

Specifically, the welded pipeline 2 before the right-angle filter is mainly used for connecting its one end to a coolant outlet of the plate heat exchanger and its other end to a front end of the flowmeter to play a connecting role. A welded butterfly valve is arranged in the welded pipeline 2 before the right-angle filter. The welded butterfly valve is normally open during normal operation, and can be manually closed when the plate heat exchanger or the flowmeter needs to be replaced or maintained. The welded pipeline 2 before the right-angle filter has a welded temperature sensor mounting base for installing the temperature sensor configured to measure the temperature of the coolant after it flows through the plate heat exchanger. The welded pipeline 2 before the right-angle filter has a welded liquid discharging stop valve port. After the stop valve and a quick coupling port are mounted, the coolant may be replenished or discharged when maintenance is required. The welded pipeline 2 before the right-angle filter has a welded corrugated stainless steel hose that can compensate for size and assembly errors.

The pump inlet welded pipe 10 is mainly used for connecting the server container liquid-outlet port 3 to the pump 19. The pump inlet welded pipe 10 has the welded corrugated stainless steel hose, which can compensate for size and assembly errors, and also can reduce the impact of vibration caused by operation of the pump on other parts. The pump inlet welded pipe 10 has a welded manual butterfly valve, which may be closed manually when needed. The pump inlet welded pipe 10 has a welded temperature sensor mounting port for mounting the temperature sensor, and the temperature sensor is configured to measure the temperature of the coolant inside the server container when it enters the heat exchange device. The pump inlet welded pipe 10 has a welded stop valve mounting port for mounting the pump inlet liquid filling/discharging port 9.

The liquid inlet pipe welded pipe 11 for the external circulation system is mainly used for connecting the liquid inlet pipe for the external circulation system to the electric regulating valve 4. The liquid inlet pipe welded pipe 11 for the external circulation system has a temperature sensor port configured to measure the liquid inlet temperature of the external circulation system. The liquid inlet pipe welded pipe 11 for the external circulation system has a port for installing the ball valve of the pressure sensor. After the ball valve is mounted, it is normally open. The pressure sensor is mounted at one end of the ball valve. When the pressure sensor needs to be maintained, the ball valve may be manually closed. The pressure sensor mounted here is configured to measure liquid inlet pressure of the external circulation system.

The pump outlet welded pipe 12 is mainly used for connecting the pump to the plate heat exchanger 24. The pump outlet welded pipe 12 has a welded check valve, which can avoid liquid backflow. The pump outlet welded pipe 12 has a welded manual butterfly valve. The manual butterfly valve is normally open during normal operation and can be manually closed when maintenance is required. The pump outlet welded pipe 12 has an automatic exhaust valve mounting port. The mounted automatic exhaust valve can automatically discharge gas when there is the gas in the server coolant circulation system. The pump outlet welded pipe 12 has the welded corrugated stainless steel hose, which can compensate for size and assembly errors, and also can reduce the impact of vibration caused by operation of the pump on other parts.

The liquid return pipe welded pipe 13 for the external circulation system is mainly used for connecting the liquid return flange 8 for the external circulation system to the plate heat exchanger 24. The liquid return pipe welded pipe 13 for the external circulation system has an automatic exhaust valve mounting port. The mounted automatic exhaust valve can automatically discharge gas when there is the gas in the external circulation system. The liquid return pipe welded pipe 13 for the external circulation system has a port for installing the ball valve of the pressure sensor. After the ball valve is mounted, it is normally open. The pressure sensor is mounted at one end of the ball valve. When the pressure sensor needs to be maintained, the ball valve may be manually closed. The pressure sensor mounted here is configured to measure liquid return pressure of the external circulation system. The liquid return pipe welded pipe 13 for the external circulation system has a welded corrugated stainless steel hose that can compensate for size and assembly errors, which is advantageous to installation and stable operation of the device.

The automatic exhaust valve 25 is mainly used for discharging the gas in the pipeline, to prevent accumulation of a large amount of gas in the pipeline from adversely affecting the normal operation of the device.

The foregoing descriptions are merely preferred embodiments of the present disclosure, and are not intended to limit the present disclosure. Any modification, equivalent replacement and improvement made within the spirit and principle of the present disclosure shall fall into the protection scope of the present disclosure.

What is claimed is:

1. A liquid cooling heat exchange device for a data room, comprising a server container, an external circulation system, a pipeline system, a sensor, a control system, and a structural member; wherein
the server container comprises a server container liquid-outlet port (3) and a server container liquid-inlet port (6); the server container liquid-outlet port (3) is connected to a coolant outlet inside the server container, and the server container liquid-inlet port (6) is connected to a coolant inlet inside the server container;
the external circulation system comprises an external circulation coolant and a heat dissipation system, the external circulation coolant enters a plate heat exchanger (24) to participate in heat exchange after the coolant is subjected to outdoor heat dissipation by means of the heat dissipation system, and the external circulation system is configured to cool the coolant in the server container by means of the plate heat exchanger (24);
the pipeline system adopts a stainless steel pipeline, and the pipeline system is configured to guide the coolant in the server container into the plate heat exchanger (24), and guide the coolant cooled by the plate heat exchanger (24) back to the server container;
the sensor is mounted in a key pipeline to monitor a parameter of a liquid inside the pipeline in real time; and
the control system is connected to the sensor and an actuator, and is configured to control the actuator by calculating a control instruction according to data collected by the sensor, to regulate a flow rate and a temperature of the coolant in the server container, thereby accurately controlling the temperature of a server.

2. The liquid cooling heat exchange device for the data room according to the claim 1, wherein the pipeline system further comprises a right-angle filter (23), and the right-angle filter (23) is arranged on a pipeline of the server container liquid-inlet port (6).

3. The liquid cooling heat exchange device for the data room according to the claim 1, wherein the sensor comprises a flowmeter (1), a temperature sensor (15), and a pressure sensor (16); the flowmeter (1) is arranged on a pipeline of the server container liquid-outlet port (3), the temperature sensor (15) is arranged on a pipeline of the server container liquid-inlet port or server container liquid-outlet port, and the pressure sensor (16) is arranged on a pipeline of the external circulation system.

4. The liquid cooling heat exchange device for the data room according to the claim 1, wherein the control system is a PLC control system or a DCS control system.

5. The liquid cooling heat exchange device for the data room according to the claim 1, wherein the actuator comprises a pump (19) and an electric regulating valve (4); the pump (19) is arranged on a pipeline of the server container liquid-outlet port (3), and the electric regulating valve (4) is arranged on a pipeline of the external circulation system.

6. The liquid cooling heat exchange device for the data room according to the claim 1, wherein the pipeline system is further provided with a manual valve, the manual valve comprises one or more of a ball valve (17), a butterfly valve (18), and a stop valve.

7. The liquid cooling heat exchange device for the data room according to the claim 1, wherein the pipeline system is further provided with a liquid filling/discharging port (9), and the liquid filling/discharging port (9) is arranged on a pipeline of the pump (19).

8. The liquid cooling heat exchange device for the data room according to the claim 1, wherein the pipeline system is further provided with a flexible pipe section, and the flexible pipe section is arranged on a pipeline of the pump (19).

9. The liquid cooling heat exchange device for the data room according to the claim 1, wherein the structural member (22) is made of stainless steel, and the structural member (22) is configured to fix the server container port, the plate heat exchanger (24), the pipeline system, the sensor, and the actuator together.

10. The liquid cooling heat exchange device for the data room according to the claim 1, wherein the plate heat exchanger (24) is configured to cool the coolant in the server container by means of the external circulation coolant, and precisely regulate a parameter of the coolant by means of the sensor and the control system, to accurately control the temperature of the server.
